(19) United States
(12) Patent Application Publication
(10) Pub. No.: US 2025/0132288 A1
(43) Pub. Date: Apr. 24, 2025

(54) PROCESS FOR FLIP CHIP PACKAGING

(71) Applicant: YIN-JUI SHIH, Changhua County (TW)

(72) Inventor: YIN-JUI SHIH, Changhua County (TW)

(21) Appl. No.: 18/918,413

(22) Filed: Oct. 17, 2024

(30) Foreign Application Priority Data
Oct. 23, 2023 (TW) 112140367

(51) Int. Cl. H01L 23/00

(52) U.S. Cl. CPC H01L 24/83; H01L 24/81; H01L 24/92; H01L 2224/81024; H01L 2224/81191; H01L 2224/81801; H01L 2224/83093; H01L 2224/83097; H01L 2224/83104; H01L 2224/92125

(57) ABSTRACT

A process for flip chip packaging includes: preparing a chip provided with a plurality of conductive bumps; preparing a wiring substrate, on which a respective welding pad is configured correspondingly to each of the conductive bumps; spraying a welding flux on each of the welding pads by utilizing a 3D array nozzle printing device; flipping and aligning the chip, and performing a metal welding operation to form a flip chip package structure; filling a liquid material to cover a substance to be cleaned on the wiring substrate; placing the flip chip package structure in a closed processing chamber, and heating the processing chamber to a predetermined temperature; and generating intermittent increasing/reducing pressure and/or intermittent vacuumizing for a gas in the processing chamber with a pressure increasing/reducing device and/or a vacuum generator, so that the substance to be cleaned is taken away from the wiring substrate.

### CROSS-REFERENCE TO RELATED APPLICATIONS

The application claims priority to Taiwan patent application No. 112140367, filed on Oct. 23, 2023, the entire contents of which are incorporated herein by reference.

### TECHNICAL FIELD

The present invention belongs to the technical field of flip chip packaging, and in particular, technically provides a process for flip chip packaging, which can reduce the quantity of a residual welding flux after metal welding as much as possible by accurately controlling a spraying range and a spraying dose of a welding flux through a 3D array nozzle printing device, supplemented by a liquid material combined with a gas flow fluctuation with intermittent pressure increasing and reducing to drive the liquid material to cause a rubbing or stirring effect, thereby improving the cleaning benefit of residues, effectively simplifying the process for flip chip packaging and greatly improving production efficiency.

### BACKGROUND

In the generation of ever-changing science and technology, high-tech electronic technologies have come out one after another, which makes more humanized and better functional electronic products constantly innovative and designed towards the trend of lightness, thinness, shortness, and smallness. To achieve the above requirements, it is necessary to meet the requirements of high-speed processing, multi-functionality, aggregation, small sizes and lightweight, and low costs of electronic components. Therefore, integrated circuit packaging technology is also developing towards miniaturization and high density. Among various packaging technologies, flip chip package (F/C package) and other high-density integrated circuit packaging technologies that adopt bumps or solder balls for electrical connection can shorten the wiring length and thereby improve the signal transmission speed, so they have gradually become the mainstream of high-density packaging.

According to the conventional process for flip chip packaging, inter-material bonding often requires the use of adhesives, especially for metal bonding. Some adhesives usually have a high acid content and corrosiveness to remove the tight oxide layer formed on the bonding surface. However, the corrosive nature of this adhesive seriously affects the performance of microelectronic components. Therefore, it is necessary to perform a further cleaning step to remove the residual adhesive on the bonding surface or the reaction residue between the adhesive and the metal oxide. There are also some adhesives that will leave some organic matter after use and leave a layer of oil ester film on the bonding surface. Such oil esters must also undergo a further cleaning step to avoid subsequent reliability issues for semiconductor components. However, when the lines on the wiring substrate become denser or the projections on the wiring substrate for bonding become smaller or the gap between the wiring substrate and the welding pad joint becomes narrower, the above residues become more and more difficult to clean. If the residual corrosive adhesive on the wiring substrate or joint is not completely removed, the reliability of the component will be greatly reduced. In addition, the above residues are cleaned by cleaning solvents commonly used at present. If improperly handled, it will have an impact on the environment, so it is necessary to make improvements.

Therefore, as regards the above problems existing in the conventional process for flip chip packaging, how to develop a packaging process that is more ideal and practical while considering economic benefits is actually the goal and direction of active research and development and breakthroughs for relevant practitioners.

In view of this, the inventor has been engaged in the manufacturing, development and design of related products for many years. Concerning the above goal, after detailed design and careful evaluation, a practical invention is finally obtained.

### SUMMARY

Technical problems to be solved: according to the conventional process for flip chip packaging, inter-material bonding often requires the use of adhesives, especially for metal bonding. Some adhesives usually have a high acid content and corrosiveness to remove the tight oxide layer formed on the bonding surface. However, the corrosive nature of this adhesive seriously affects the performance of microelectronic components. Therefore, it is necessary to perform a further cleaning step to remove the residual adhesive on the bonding surface or the reaction residue between the adhesive and the metal oxide. However, when the lines on the wiring substrate become denser or the projections on the wiring substrate for bonding become smaller or the gap between the wiring substrate and the welding pad joint becomes narrower, the above residues become more and more difficult to clean, so it is necessary to make improvements.

Technical features for solving problems: in order to improve the above problems, the present invention provides a process for flip chip packaging, including steps of: a. preparing a chip, where the chip is provided with an active surface, a plurality of conductive bumps are disposed on the active surface, and a component of the conductive bump is at least one of tin, silver, copper, gold, indium, lead, bismuth, zinc, and nickel, or other materials that are beneficial to welding. b. preparing a wiring substrate, where the wiring substrate is provided with a bearing surface, and a respective welding pad is configured on the bearing surface corresponding to each of the conductive bumps.
c. spraying a welding flux on a surface of each of the welding pads by utilizing a 3D array nozzle printing device, where through a program setting of the 3D array nozzle printing device, a spraying range and a spraying dose of the welding flux can be accurately controlled, and spraying outside an area of each of the welding pads can be effectively avoided.
d. flipping and aligning the chip, so that the active surface of the chip is configured toward the bearing surface of the wiring substrate, and each of the conductive bumps is bonded to each of the welding pads via the welding flux, and continuously performing a metal welding operation, so that the chip is electrically and structurally connected to each of the welding pads on the wiring substrate by each of the conductive bumps to form a flip chip package structure, and signal transmission can be carried out between the wiring substrate and the chip.
e. filling a liquid material between the wiring substrate and the chip to cover a substance to be cleaned on the wiring substrate.
f. placing the flip chip package structure containing the liquid material in a closed processing chamber, and heating the processing chamber to a predetermined temperature, where the predetermined temperature is between 25° C. and 200° C. to match viscosity of the liquid material, so as to increase fluidity of the liquid material.
g. generating intermittent vacuumizing for a gas in the processing chamber with a vacuum generator to generate a wavy gas flow which is a fluctuation under vacuum ranging from a maximum value of no more than 1 atmospheric pressure to a minimum value of 10⁻⁵ atmospheric pressure for an intermittent fluctuation, and causing a fluctuation change of the liquid material by utilizing a fluctuation change of gas vacuum suction, so that the liquid material in contact with the substance to be cleaned is scrubbed by friction with a larger amplitude back and forth, and the substance to be cleaned adhered to the wiring substrate is more efficiently taken away from the wiring substrate, so as to achieve an effect that conventional solution cleaning cannot reach.

The present invention provides another process for flip chip packaging, including steps of: a. preparing a chip, where the chip is provided with an active surface, a plurality of conductive bumps are disposed on the active surface, and a component of the conductive bump is at least one of tin, silver, copper, gold, indium, lead, bismuth, zinc, and nickel, or other materials that are beneficial to welding. b. preparing a wiring substrate, where the wiring substrate is provided with a bearing surface, and a respective welding pad is configured on the bearing surface corresponding to each of the conductive bumps.
c. spraying a welding flux on a surface of each of the welding pads by utilizing a 3D array nozzle printing device, where through a program setting of the 3D array nozzle printing device, a spraying range and a spraying dose of the welding flux can be accurately controlled, and spraying outside an area of each of the welding pads can be effectively avoided.
d. flipping and aligning the chip, so that the active surface of the chip is configured toward the bearing surface of the wiring substrate, and each of the conductive bumps is bonded to each of the welding pads via the welding flux, and continuously performing a metal welding operation, so that the chip is electrically and structurally connected to each of the welding pads on the wiring substrate by each of the conductive bumps to form a flip chip package structure, and signal transmission can be carried out between the wiring substrate and the chip.
e. filling a liquid material between the wiring substrate and the chip to cover a substance to be cleaned on the wiring substrate.
f. placing the flip chip package structure containing the liquid material in a closed processing chamber, and heating the processing chamber to a predetermined temperature, where the predetermined temperature is between 25° C. and 200° C. to match viscosity of the liquid material, so as to increase fluidity of the liquid material.
g. generating intermittent pressure increasing and reducing and intermittent vacuumizing for a gas in the chamber with a pressure increasing and reducing device and a vacuum generator to generate a wavy gas flow which is a fluctuation from high pressure to vacuum ranging from a maximum value of 50 atmospheric pressure to a minimum value of 10⁻⁵ atmospheric pressure for an intermittent fluctuation, and causing a fluctuation change of the liquid material by utilizing a fluctuation change of the gas, so that the liquid material in contact with the substance to be cleaned is scrubbed by friction back and forth, and the substance to be cleaned adhered to the wiring substrate is more efficiently taken away from the wiring substrate, so as to achieve an effect that conventional solution cleaning cannot reach.

The present invention provides yet another process for flip chip packaging, including steps of: a. preparing a chip, where the chip is provided with an active surface, a plurality of conductive bumps are disposed on the active surface, and a component of the conductive bump is at least one of tin, silver, copper, gold, indium, lead, bismuth, zinc, and nickel, or other materials that are beneficial to welding. b. preparing a wiring substrate, where the wiring substrate is provided with a bearing surface, and a respective welding pad is configured on the bearing surface corresponding to each of the conductive bumps.
c. spraying a welding flux on a surface of each of the welding pads by utilizing a 3D array nozzle printing device, where through a program setting of the 3D array nozzle printing device, a spraying range and a spraying dose of the welding flux can be accurately controlled, and spraying outside an area of each of the welding pads can be effectively avoided.
d. flipping and aligning the chip, so that the active surface of the chip is configured toward the bearing surface of the wiring substrate, and each of the conductive bumps is bonded to each of the welding pads via the welding flux, and continuously performing a metal welding operation, so that the chip is electrically and structurally connected to each of the welding pads on the wiring substrate by each of the conductive bumps to form a flip chip package structure, and signal transmission can be carried out between the wiring substrate and the chip.
e. filling a liquid material between the wiring substrate and the chip to cover a substance to be cleaned on the wiring substrate.
f. placing the flip chip package structure containing the liquid material in a closed processing chamber, and heating the processing chamber to a predetermined temperature, where the predetermined temperature is between 25° C. and 200° C. to match viscosity of the liquid material, so as to increase fluidity of the liquid material.
g. generating intermittent pressure increasing and reducing for a gas in the processing chamber with a pressure increasing and reducing device to generate a wavy gas flow which is a fluctuation from high pressure to 1 atmospheric pressure ranging from a maximum value of 50 atmospheric pressure to a minimum value of 1 atmospheric pressure for an intermittent fluctuation, and causing a fluctuation change of the liquid material by utilizing a fluctuation change of the gas, so that the liquid material in contact with the substance to be cleaned is scrubbed by friction back and forth, and the substance to be cleaned adhered to the wiring substrate is more efficiently taken away from the wiring substrate, so as to achieve an effect that conventional solution cleaning cannot reach.

As mentioned above, the welding flux adopted is a liquid welding flux, and the liquid welding flux has viscosity in a range of 1 centipoise (cp) to 100 cp.

As mentioned above, the substance to be cleaned is a welding flux, a welding flux residue, an oil ester, a photoresist, or a product of the process.

As mentioned above, the liquid material is a underfill, the underfill may include a hard particle, the hard particle rolls back and forth with a fluctuation of the underfill, and an effect of scrubbing by friction is increased by the hard particle to help clean the substance to be removed.

As described above, a component of the underfill is epoxy resin doped with a filler such as silicon dioxide (SiO2) powder.

Compared with the efficacy of the prior art, the process for flip chip packaging of the present invention accurately controls the spraying range and the spraying dose of the welding flux by the 3D array nozzle printing device, so that the residual welding flux rafter the metal welding operation is extremely small, supplemented by the fluctuation change of the liquid material caused by controlling the fluctuation change of the gas in the processing chamber to cause the fluctuation change of the liquid material to generate a back-and-forth rubbing cleaning effect like laundry, or to accelerate the dissolution of the substance to be cleaned in the liquid material, such as adding sugar to water and stirring to accelerate the sugar dissolving effect, so that the liquid material in contact with the substance to be cleaned is scrubbed by friction back and forth, and the substance to be cleaned adhered to the wiring substrate is taken away from the wiring substrate, thereby improving the cleaning benefit of residues, effectively simplifying the process for flip chip packaging and greatly improving production efficiency; and in addition, heating the temperature of the processing chamber to between 25° C. and 200° C. in the processing chamber also causes the oil ester film, part of the substance to be cleaned or the water vapor adsorbed inside the wiring substrate to volatilize due to heating to produce a gas, which can also be discharged from the liquid material through the fluctuation under vacuum, the fluctuation from high pressure to 1 atmospheric pressure or the fluctuation from high pressure to vacuum, and by the fluctuation change of the liquid material caused by the fluctuation change of the gas.

Regarding the technology, means and efficacy adopted in the present invention, a number of preferred embodiments are listed and described in detail below with reference to the drawings. It is believed that an in-depth and specific understanding can be obtained for the above purposes, structures and features of the present invention therefrom.

### BRIEF DESCRIPTION OF DRAWINGS

FIG. 1 is a flow chart of a process for flip chip packaging according to an embodiment of the present invention.

FIG. 2 is a flow chart of a process for flip chip packaging according to another embodiment of the present invention.

FIG. 3 is a flow chart of a process for flip chip packaging according to yet another embodiment of the present invention.

FIGS. 4A to 4F are schematic cross-sectional diagrams of the process for flip chip packaging of FIGS. 1 to 3.

### REFERENCE NUMERALS

21a-27a step
21b-27b step
21c-27c step
300 flip chip package structure
310 chip
311 active surface
320 conductive bump
330 wiring substrate
331 bearing surface
332 welding pad
340 3D array nozzle printing device
341 welding flux sprayed coating
350 nozzle
410 liquid material
510 processing chamber

### DETAILED DESCRIPTION OF THE EMBODIMENTS

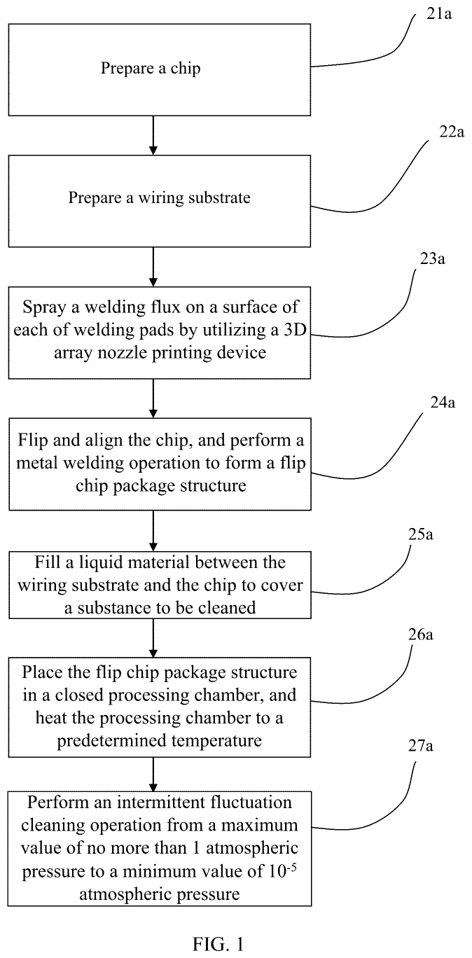

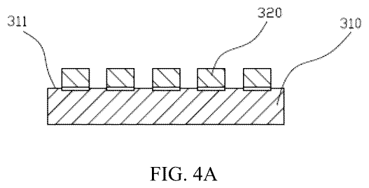

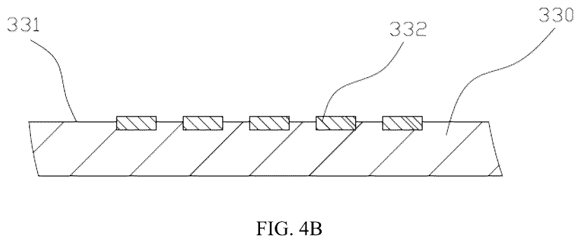

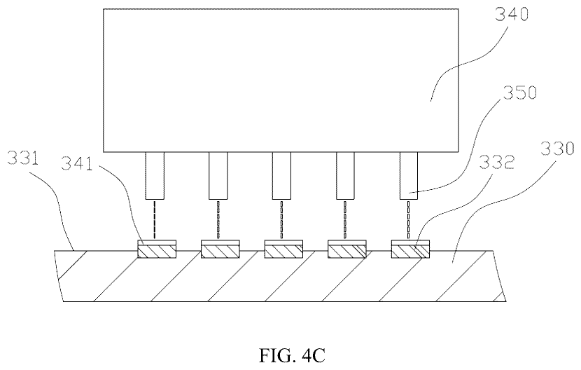

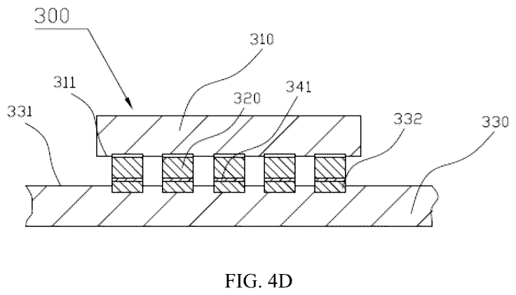

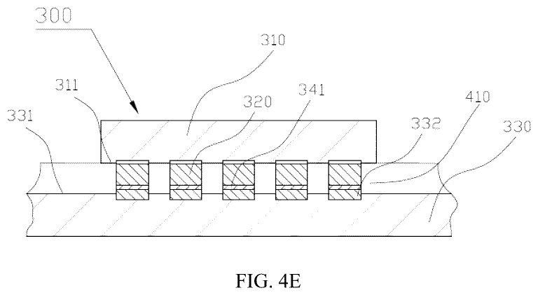

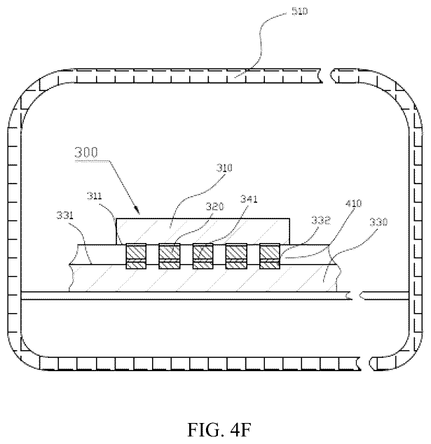

Referring to FIG. 1 and FIGS. 4A to 4F, where FIG. 1 is a flow chart of a process for flip chip packaging according to an embodiment of the present invention, and FIGS. 4A to 4F are schematic cross-sectional diagrams of this process for flip chip packaging, the present invention provides a process for flip chip packaging, including steps of: a. (step 21a) preparing a chip 310, where the chip 310 is provided with an active surface 311, a plurality of conductive bumps 320 are disposed on the active surface 311 (as shown in FIG. 4A), the conductive bump 320 is a solder bump made by a general bumping process, and a component of the conductive bump is at least one of tin, silver, copper, gold, indium, lead, bismuth, zinc, and nickel, or other materials that are beneficial to welding.
b. (step 22a) preparing a wiring substrate 330, where the wiring substrate 330 is provided with a bearing surface 331, and a respective welding pad 332 is configured on the bearing surface 331 corresponding to each of the conductive bumps 320 (as shown in FIG. 4B).
c. (step 23a) spraying a welding flux on a surface of each of the welding pads 332 by utilizing a 3D array nozzle printing device 340, where through a program setting of the 3D array nozzle printing device 340, a spraying range and a spraying dose of the welding flux can be accurately controlled, and overflow of the welding flux sprayed on the surface of each of the welding pads 332 is effectively avoided, where the welding flux is sprayed by using the 3D array nozzle printing device 340 to accurately locate positions of each welding pad 332 on the wiring substrate 330 and a desired spraying range by defining coordinates of a plurality of nozzles 350 in advance on a graphic designed by a computer, and the 3D array nozzle printing device 340 stacks a plurality of welding flux sprayed coatings 341 imitating the 3D graphic layer by layer according to the design (as shown in FIG. 4C), where the welding flux adopted is liquid welding flux, and its main function is to remove oxides on surfaces of a solder and a base material to be welded, achieve necessary cleanliness on a welded surface, prevent re-oxidation of the surface during welding, reduce surface tension of the liquid solder, and significantly improve wetting performance.
d. (step 24a) flipping and aligning the chip 310, so that the active surface 311 of the chip 310 is configured toward the bearing surface 331 of the wiring substrate 330, and each of the conductive bumps 320 is bonded to each of the welding pads 332 via the welding flux (as shown in FIG. 4D), and continuously performing a metal welding operation, so that the chip 310 is electrically and structurally connected to each of the welding pads 332 on the wiring substrate 330 by each of the conductive bumps 320 to form a flip chip package structure 300, and signal transmission can be carried out between the wiring substrate 330 and the chip 310, where the metal bonding (e.g. reflow welding) performed herein is to metal bond the aligned chip 310 to the wiring substrate 330 and each of the conductive bumps 320 and to each of the welding pads 332, so that each of the conductive bumps 320 in a thermally melted or semi-melted state is bonded to each of the welding pads 332 on the bearing surface 331 of the wiring substrate 330.
e. (step 25a) filling a liquid material 410 between the wiring substrate 330 and the chip 310 to cover a substance to be cleaned on the wiring substrate (as shown in FIG. 4E).
f. (step 26a) placing the flip chip package structure 300 containing the liquid material 410 in a closed processing chamber 510 (as shown in FIG. 4F), and heating the processing chamber 510 to a predetermined temperature, where the predetermined temperature is between 25° C. and 200° C. to match viscosity of the liquid material, so as to increase fluidity of the liquid material.
g. (step 27a) generating intermittent vacuumizing for a gas in the processing chamber 510 with a vacuum generator (not shown) to generate a wavy gas flow which is a fluctuation under vacuum ranging from a maximum value of no more than 1 atmospheric pressure to a minimum value of 10⁻⁵ atmospheric pressure for an intermittent fluctuation, and causing a fluctuation change of the liquid material 410 by utilizing a fluctuation change of gas vacuum suction, where the liquid material 410 exists between the chip 310 and the wiring substrate 330, and since the capillary force between them and the surface tension of the liquid material 410, the liquid material 410 can be pulled to generate a greater fluctuation without any overflow issues, so that the liquid material 410 in contact with the substance to be cleaned is scrubbed by friction with a larger amplitude back and forth, and the substance to be cleaned adhered to the wiring substrate 330 is more efficiently taken away from the wiring substrate 330, so as to achieve an effect that conventional solution cleaning cannot reach, and pulling the liquid fluctuation of the liquid material 410 through the fluctuation of the gas can reduce direct energy transfer and relieve damage to objects or splashing of the liquid material 410 caused by excessive fluctuations.

As mentioned above, the liquid welding flux has viscosity in a range of 1 centipoise (cp) to 100 cp.

As mentioned above, the substance to be cleaned is a welding flux, a welding flux residue, an oil ester, a photoresist, or a product of the process.

As mentioned above, the liquid material 410 is a underfill, the underfill may include a hard particle, the hard particle rolls back and forth with a fluctuation of the underfill, and an effect of scrubbing by friction is increased by the hard particle to help clean the substance to be removed.

As described above, a component of the underfill is epoxy resin doped with a filler such as silicon dioxide (SiO2) powder.

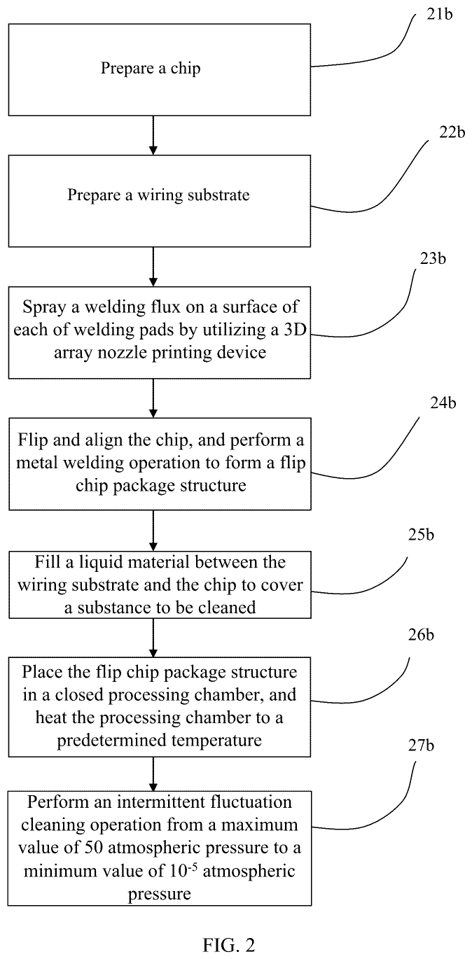

Referring to FIG. 2 and FIGS. 4A to 4F, where FIG. 2 is a flow chart of a process for flip chip packaging according to another embodiment of the present invention, and FIGS. 4A to 4F are schematic cross-sectional diagrams of this process for flip chip packaging, the present invention provides a process for flip chip packaging, including steps of: a. (step 21b) preparing a chip 310, where the chip 310 is provided with an active surface 311, a plurality of conductive bumps 320 are disposed on the active surface 311 (as shown in FIG. 4A), the conductive bump 320 is a solder bump made by a general bumping process, and a component of the conductive bump is at least one of tin, silver, copper, gold, indium, lead, bismuth, zinc, and nickel, or other materials that are beneficial to welding.
b. (step 22b) preparing a wiring substrate 330, where the wiring substrate 330 is provided with a bearing surface 331, and a respective welding pad 332 is configured on the bearing surface 331 corresponding to each of the conductive bumps 320 (as shown in FIG. 4B).
c. (step 23b) spraying a welding flux on a surface of each of the welding pads 332 by utilizing a 3D array nozzle printing device 340, where through a program setting of the 3D array nozzle printing device 340, a spraying range and a spraying dose of the welding flux can be accurately controlled, and overflow of the welding flux sprayed on the surface of each of the welding pads 332 is effectively avoided, where the welding flux is sprayed by using the 3D array nozzle printing device 340 to accurately locate positions of each welding pad 332 on the wiring substrate 330 and a desired spraying range by defining coordinates of a plurality of nozzles 350 in advance on a graphic designed by a computer, and the 3D array nozzle printing device 340 stacks a plurality of welding flux sprayed coatings 341 imitating the 3D graphic layer by layer according to the design (as shown in FIG. 4C), where the welding flux adopted is liquid welding flux, and its main function is to remove oxides on surfaces of a solder and a base material to be welded, achieve necessary cleanliness on a welded surface, prevent re-oxidation of the surface during welding, reduce surface tension of the liquid solder, and significantly improve wetting performance.
d. (step 24b) flipping and aligning the chip 310, so that the active surface 311 of the chip 310 is configured toward the bearing surface 331 of the wiring substrate 330, and each of the conductive bumps 320 is bonded to each of the welding pads 332 via the welding flux (as shown in FIG. 4D), and continuously performing a metal welding operation, so that the chip 310 is electrically and structurally connected to each of the welding pads 332 on the wiring substrate 330 by each of the conductive bumps 320 to form a flip chip package structure 300, and signal transmission can be carried out between the wiring substrate 330 and the chip 310, where the metal bonding (e.g. reflow welding) performed herein is to metal bond the aligned chip 310 to the wiring substrate 330 and each of the conductive bumps 320 and to each of the welding pads 332, so that each of the conductive bumps 320 in a thermally melted or semi-melted state is bonded to each of the welding pads 332 on the bearing surface 331 of the wiring substrate 330.
e. (step 25b) filling a liquid material 410 between the wiring substrate 330 and the chip 310 to cover a substance to be cleaned on the wiring substrate (as shown in FIG. 4E).
f. (step 26b) placing the flip chip package structure 300 containing the liquid material 410 in a closed processing chamber 510 (as shown in FIG. 4F), and heating the processing chamber 510 to a predetermined temperature, where the predetermined temperature is between 25° C. and 200° C. to match viscosity of the liquid material, so as to increase fluidity of the liquid material.
g. (step 27b) generating intermittent pressure increasing and reducing and intermittent vacuumizing for a gas in the processing chamber 510 with a pressure increasing and reducing device (not shown) and a vacuum generator (not shown) to generate a wavy gas flow which is a fluctuation from high pressure to vacuum ranging from a maximum value of 50 atmospheric pressure to a minimum value of 10⁻⁵ atmospheric pressure for an intermittent fluctuation, and causing a fluctuation change of the liquid material 410 by utilizing a fluctuation change of the gas, where the liquid material 410 exists between the chip 310 and the wiring substrate 330, and since the capillary force between them and the surface tension of the liquid material 410, the liquid material 410 can be pulled to generate a greater fluctuation without any overflow issues, so that the liquid material 410 in contact with the substance to be cleaned is scrubbed by friction back and forth, and the substance to be cleaned adhered to the wiring substrate 330 is more efficiently taken away from the wiring substrate 330, so as to achieve an effect that conventional solution cleaning cannot reach, and pulling the liquid fluctuation of the liquid material 410 through the fluctuation of the gas can reduce direct energy transfer and relieve damage to objects or splashing of the liquid material 410 caused by excessive fluctuations.

As mentioned above, the liquid welding flux has viscosity in a range of 1 centipoise (cp) to 100 cp.

As mentioned above, the substance to be cleaned is a welding flux, a welding flux residue, an oil ester, a photoresist, or a product of the process.

As mentioned above, the liquid material 410 is a underfill, the underfill may include a hard particle, the hard particle rolls back and forth with a fluctuation of the underfill, and an effect of scrubbing by friction is increased by the hard particle to help clean the substance to be removed.

As described above, a component of the underfill is epoxy resin doped with a filler such as silicon dioxide (SiO2) powder.

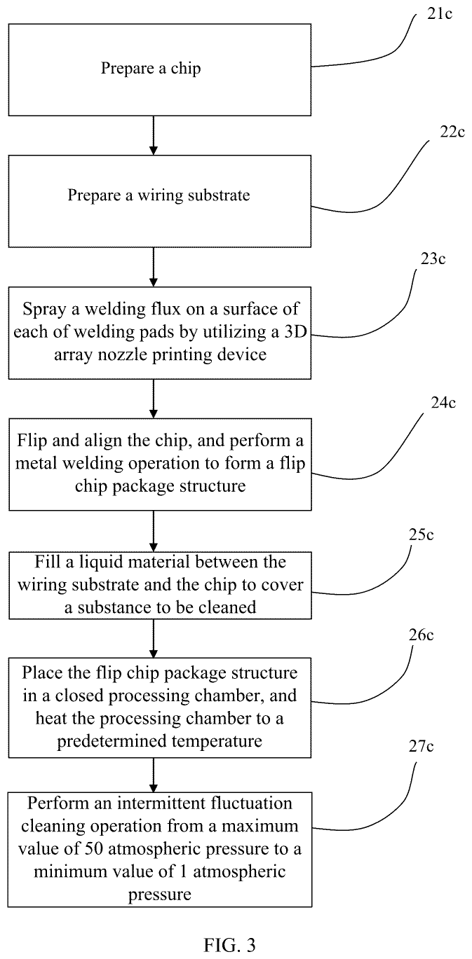

Referring to FIG. 3 and FIGS. 4A to 4F, where FIG. 3 is a flow chart of a process for flip chip packaging according to yet another embodiment of the present invention, and FIGS. 4A to 4F are schematic cross-sectional diagrams of this process for flip chip packaging, the present invention provides a process for flip chip packaging, including steps of: a. (step 21c) preparing a chip 310, where the chip 310 is provided with an active surface 311, a plurality of conductive bumps 320 are disposed on the active surface 311 (as shown in FIG. 4A), the conductive bump 320 is a solder bump made by a general bumping process, and a component of the conductive bump is at least one of tin, silver, copper, gold, indium, lead, bismuth, zinc, and nickel, or other materials that are beneficial to welding.
b. (step 22c) preparing a wiring substrate 330, where the wiring substrate 330 is provided with a bearing surface 331, and a respective welding pad 332 is configured on the bearing surface 331 corresponding to each of the conductive bumps 320 (as shown in FIG. 4B).
c. (step 23c) spraying a welding flux on a surface of each of the welding pads 332 by utilizing a 3D array nozzle printing device 340, where through a program setting of the 3D array nozzle printing device 340, a spraying range and a spraying dose of the welding flux can be accurately controlled, and overflow of the welding flux sprayed on the surface of each of the welding pads 332 is effectively avoided, where the welding flux is sprayed by using the 3D array nozzle printing device 340 to accurately locate positions of each welding pad 332 on the wiring substrate 330 and a desired spraying range by defining coordinates of a plurality of nozzles 350 in advance on a graphic designed by a computer, and the 3D array nozzle printing device 340 stacks a plurality of welding flux sprayed coatings 341 imitating the 3D graphic layer by layer according to the design (as shown in FIG. 4C), where the welding flux adopted is liquid welding flux, and its main function is to remove oxides on surfaces of a solder and a base material to be welded, achieve necessary cleanliness on a welded surface, prevent re-oxidation of the surface during welding, reduce surface tension of the liquid solder, and significantly improve wetting performance.
d. (step 24c) flipping and aligning the chip 310, so that the active surface 311 of the chip 310 is configured toward the bearing surface 331 of the wiring substrate 330, and each of the conductive bumps 320 is bonded to each of the welding pads 332 via the welding flux (as shown in FIG. 4D), and continuously performing a metal welding operation, so that the chip 310 is electrically and structurally connected to each of the welding pads 332 on the wiring substrate 330 by each of the conductive bumps 320 to form a flip chip package structure 300, and signal transmission can be carried out between the wiring substrate 330 and the chip 310, where the metal bonding (e.g. reflow welding) performed herein is to metal bond the aligned chip 310 to the wiring substrate 330 and each of the conductive bumps 320 and to each of the welding pads 332, so that each of the conductive bumps 320 in a thermally melted or semi-melted state is bonded to each of the welding pads 332 on the bearing surface 331 of the wiring substrate 330.
e. (step 25c) filling a liquid material 410 between the wiring substrate 330 and the chip 310 to cover a substance to be cleaned on the wiring substrate (as shown in FIG. 4E).
f. (step 26c) placing the flip chip package structure 300 containing the liquid material 410 in a closed processing chamber 510 (as shown in FIG. 4F), and heating the processing chamber 510 to a predetermined temperature, where the predetermined temperature is between 25° C. and 200° C. to match viscosity of the liquid material, so as to increase fluidity of the liquid material.
g. (step 27c) generating intermittent pressure increasing and reducing for a gas in the processing chamber 510 with a pressure increasing and reducing device (not shown) to generate a wavy gas flow which is a fluctuation from a high pressure to 1 atmospheric pressure ranging from a maximum value of 50 atmospheric pressure to a minimum value of 1 atmospheric pressure for an intermittent fluctuation, and causing a fluctuation change of the liquid material 410 by utilizing a fluctuation change of the gas, where the liquid material 410 exists between the chip 310 and the wiring substrate 330, and since the capillary force between them and the surface tension of the liquid material 410, the liquid material 410 can be pulled to generate a greater fluctuation without any overflow issues, so that the liquid material 410 in contact with the substance to be cleaned is scrubbed by friction back and forth, and the substance to be cleaned adhered to the wiring substrate 330 is more efficiently taken away from the wiring substrate 330, so as to achieve an effect that conventional solution cleaning cannot reach, and pulling the liquid fluctuation of the liquid material through the fluctuation of the gas can reduce direct energy transfer and relieve damage to objects or splashing of the liquid material 410 caused by excessive fluctuations.

As mentioned above, the liquid welding flux has viscosity in a range of 1 centipoise (cp) to 100 cp.

As mentioned above, the substance to be cleaned is a welding flux, a welding flux residue, an oil ester, a photoresist, or a product of the process.

As mentioned above, the liquid material 410 is a underfill, the underfill may include a hard particle, the hard particle rolls back and forth with a fluctuation of the underfill, and an effect of scrubbing by friction is increased by the hard particle to help clean the substance to be removed.

As described above, a component of the underfill is epoxy resin doped with a filler such as silicon dioxide (SiO2) powder.

The foregoing is a specific description of the technical features of the present invention in relation to a preferred embodiment of the present invention; however, those skilled in the art can make changes and modifications to the present invention without departing from the spirit and principles of the present invention, and these changes and modifications should be covered within the scope defined by the claims below.

What is claimed is:

1. A process for flip chip packaging, comprising steps of:
(a) preparing a chip, wherein the chip is provided with an active surface, and a plurality of conductive bumps are disposed on the active surface;
(b) preparing a wiring substrate, wherein the wiring substrate is provided with a bearing surface, and a respective welding pad is configured on the bearing surface corresponding to each of the conductive bumps;
(c) spraying a welding flux on a surface of each of the welding pads by utilizing a 3D array nozzle printing device, and controlling a spraying range and a spraying dose of the welding flux through a program setting of the 3D array nozzle printing device;
(d) flipping and aligning the chip, so that the active surface of the chip is configured toward the bearing surface of the wiring substrate, and each of the conductive bumps is bonded to each of the welding pads via the welding flux, and continuously performing a metal welding operation, so that the chip is electrically and structurally connected to each of the welding pads on the wiring substrate by each of the conductive bumps to form a flip chip package structure;
(e) filling a liquid material between the wiring substrate and the chip to cover a substance to be cleaned on the wiring substrate;
(f) placing the flip chip package structure containing the liquid material in a closed processing chamber, and heating the processing chamber to a predetermined temperature, wherein the predetermined temperature is between 25° C. and 200° C. to match viscosity of the liquid material; and
(g) generating intermittent vacuumizing for a gas in the processing chamber with a vacuum generator to generate a wavy gas flow which is a fluctuation under vacuum ranging from a maximum value of no more than 1 atmospheric pressure to a minimum value of 10⁻⁵ atmospheric pressure for an intermittent fluctuation, and causing a fluctuation change of the liquid material by utilizing a fluctuation change of gas vacuum suction, so that the liquid material in contact with the substance to be cleaned is scrubbed by friction with a larger amplitude back and forth, and the substance to be cleaned adhered to the wiring substrate is more efficiently taken away from the wiring substrate.

2. The process for flip chip packaging according to claim 1, wherein the welding flux is a liquid welding flux, and the liquid welding flux has viscosity in a range of 1 centipoise (cp) to 100 cp.

3. The process for flip chip packaging according to claim 1, wherein the substance to be cleaned is a welding flux, a welding flux residue, an oil ester, a photoresist, or a product of the process.

4. The process for flip chip packaging according to claim 1, wherein the liquid material is a underfill, the underfill is capable of comprising a hard particle, the hard particle rolls back and forth with a fluctuation of the underfill, and an effect of scrubbing by friction is increased by the hard particle.

5. The process for flip chip packaging according to claim 4, wherein a component of the underfill is epoxy resin.

6. A process for flip chip packaging, comprising steps of:
(a) preparing a chip, wherein the chip is provided with an active surface, and a plurality of conductive bumps are disposed on the active surface;
(b) preparing a wiring substrate, wherein the wiring substrate is provided with a bearing surface, and a respective welding pad is configured on the bearing surface corresponding to each of the conductive bumps;
(c) spraying a welding flux on a surface of each of the welding pads by utilizing a 3D array nozzle printing device, and controlling a spraying range and a spraying dose of the welding flux through a program setting of the 3D array nozzle printing device;
(d) flipping and aligning the chip, so that the active surface of the chip is configured toward the bearing surface of the wiring substrate, and each of the conductive bumps is bonded to each of the welding pads via the welding flux, and continuously performing a metal welding operation, so that the chip is electrically and structurally connected to each of the welding pads on the wiring substrate by each of the conductive bumps to form a flip chip package structure;
(e) filling a liquid material between the wiring substrate and the chip to cover a substance to be cleaned on the wiring substrate;
(f) placing the flip chip package structure containing the liquid material in a closed processing chamber, and heating the processing chamber to a predetermined temperature, wherein the predetermined temperature is between 25° C. and 200° C. to match viscosity of the liquid material; and
(g) generating intermittent pressure increasing and reducing and intermittent vacuumizing for a gas in the chamber with a pressure increasing and reducing device and a vacuum generator to generate a wavy gas flow which is a fluctuation from high pressure to vacuum ranging from a maximum value of 50 atmospheric pressure to a minimum value of 10⁻⁵ atmospheric pressure for an intermittent fluctuation, and causing a fluctuation change of the liquid material by utilizing a fluctuation change of the gas, so that the liquid material in contact with the substance to be cleaned is scrubbed by friction back and forth, and the substance to be cleaned adhered to the wiring substrate is more efficiently taken away from the wiring substrate.

7. The process for flip chip packaging according to claim 6, wherein the welding flux is a liquid welding flux, and the liquid welding flux has viscosity in a range of 1 centipoise (cp) to 100 cp.

8. The process for flip chip packaging according to claim 6, wherein the substance to be cleaned is a welding flux, a welding flux residue, an oil ester, a photoresist, or a product of the process.

9. The process for flip chip packaging according to claim 6, wherein the liquid material is a underfill, the underfill is capable of comprising a hard particle, the hard particle rolls back and forth with a fluctuation of the underfill, and an effect of scrubbing by friction is increased by the hard particle.

10. The process for flip chip packaging according to claim 9, wherein a component of the underfill is epoxy resin.

11. A process for flip chip packaging, comprising steps of:
(a) preparing a chip, wherein the chip is provided with an active surface, and a plurality of conductive bumps are disposed on the active surface;
(b) preparing a wiring substrate, wherein the wiring substrate is provided with a bearing surface, and a respective welding pad is configured on the bearing surface corresponding to each of the conductive bumps;
(c) spraying a welding flux on a surface of each of the welding pads by utilizing a 3D array nozzle printing device, and controlling a spraying range and a spraying dose of the welding flux through a program setting of the 3D array nozzle printing device;
(d) flipping and aligning the chip, so that the active surface of the chip is configured toward the bearing surface of the wiring substrate, and each of the conductive bumps is bonded to each of the welding pads via the welding flux, and continuously performing a metal welding operation, so that the chip is electrically and structurally connected to each of the welding pads on the wiring substrate by each of the conductive bumps to form a flip chip package structure;
(e) filling a liquid material between the wiring substrate and the chip to cover a substance to be cleaned on the wiring substrate;
(f) placing the flip chip package structure containing the liquid material in a closed processing chamber, and heating the processing chamber to a predetermined temperature, wherein the predetermined temperature is between 25° C. and 200° C. to match viscosity of the liquid material; and
(g) generating intermittent pressure increasing and reducing for a gas in the processing chamber with a pressure increasing and reducing device to generate a wavy gas flow which is a fluctuation from high pressure to 1 atmospheric pressure ranging from a maximum value of 50 atmospheric pressure to a minimum value of 1 atmospheric pressure for an intermittent fluctuation, and causing a fluctuation change of the liquid material by utilizing a fluctuation change of the gas, so that the liquid material in contact with the substance to be cleaned is scrubbed by friction back and forth, and the substance to be cleaned adhered to the wiring substrate is more efficiently taken away from the wiring substrate.

12. The process for flip chip packaging according to claim 11, wherein the welding flux is a liquid welding flux, and the liquid welding flux has viscosity in a range of 1 centipoise (cp) to 100 cp.

13. The process for flip chip packaging according to claim 11, wherein the substance to be cleaned is a welding flux, a welding flux residue, an oil ester, a photoresist, or a product of the process.

14. The process for flip chip packaging according to claim 11, wherein the liquid material is a underfill, the underfill is capable of comprising a hard particle, the hard particle rolls back and forth with a fluctuation of the underfill, and an effect of scrubbing by friction is increased by the hard particle.

15. The process for flip chip packaging according to claim 14, wherein a component of the underfill is epoxy resin.
